(19) United States
(12) Patent Application Publication
(10) Pub. No.: US 2009/0250092 A1
(43) Pub. Date: Oct. 8, 2009

(54) SOLAR CELL PANEL

(75) Inventor: CHIH-MING LAI, Chu-Nan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/265,099

(22) Filed: Nov. 5, 2008

(30) Foreign Application Priority Data
Apr. 2, 2008 (CN) 200810300822.6

(51) Int. Cl. H01L 31/042

(52) U.S. Cl. 136/244

(57) ABSTRACT

A solar cell panel includes a light-pervious substrate, a photo-catalyst film, a light source and at least one solar cell. The substrate has a bottom surface and an opposite top surface. The photo-catalyst film is formed on the bottom surface. The light source is configured for emitting light having a given wavelength to activate the photo-catalyst film to decompose contaminants thereon. The at least one solar cell is positioned on the top surface of the substrate to absorb and convert light into electric energy.

### BACKGROUND

1. Field of the Invention

The present invention generally relates to solar cell panels, and particularly to a solar cell panel having self-cleaning capability.

2. Description of Related Art

Photovoltaic devices, i.e., solar cells, are capable of converting solar light into usable electric energy. The energy conversion occurs as the result of what is known as the photovoltaic effect. Solar light impinging on the solar cell and absorbed by an active region of semiconductor material generates electricity.

The solar cell offers a clean and effective inexhaustible source of energy. Particularly, the solar cell installed on a roof of a house has been recently proposed and gradually progressed to spread. However, such solar cell may easily be polluted by many kinds of contaminants in the air. The contaminants may be deposited on surfaces of the solar cell, thus restricting solar light from efficiently impinging the solar cell and decreasing the converting efficiency of the solar cell.

What is needed, therefore, is a solar cell panel which can overcome the above shortcomings.

### SUMMARY

A solar cell panel includes a light-pervious substrate, a photo-catalyst film, a light source and at least one solar cell. The substrate has a bottom surface and an opposite top surface. The photo-catalyst film is formed on the bottom surface. The light source is configured for emitting light having a given wavelength to activate the photo-catalyst film to decompose contaminants thereon. The at least one solar cell is positioned on the top surface to absorb and convert light into electric energy.

Other advantages and novel features of the present solar cell panel will become more apparent from the following detailed description when taken in conjunction with the accompanying drawings, in which:

### BRIEF DESCRIPTION OF THE DRAWINGS

Many aspects of the present solar cell panel can be better understood with reference to the following drawings. The components in the drawings are not necessarily drawn to scale, the emphasis instead being placed upon clearly illustrating the principles of the present solar cell panel. Moreover, in the drawings, like reference numerals designate corresponding parts throughout the several views.

FIG. 1 is a schematic view of a solar cell panel, in accordance with an exemplary embodiment.

FIG. 2 is a schematic, side view of the solar cell panel of FIG. 1.

FIG. 3 is similar to FIG. 2, but showing an alternative embodiment of the solar cell panel.

### DETAILED DESCRIPTION OF EMBODIMENTS

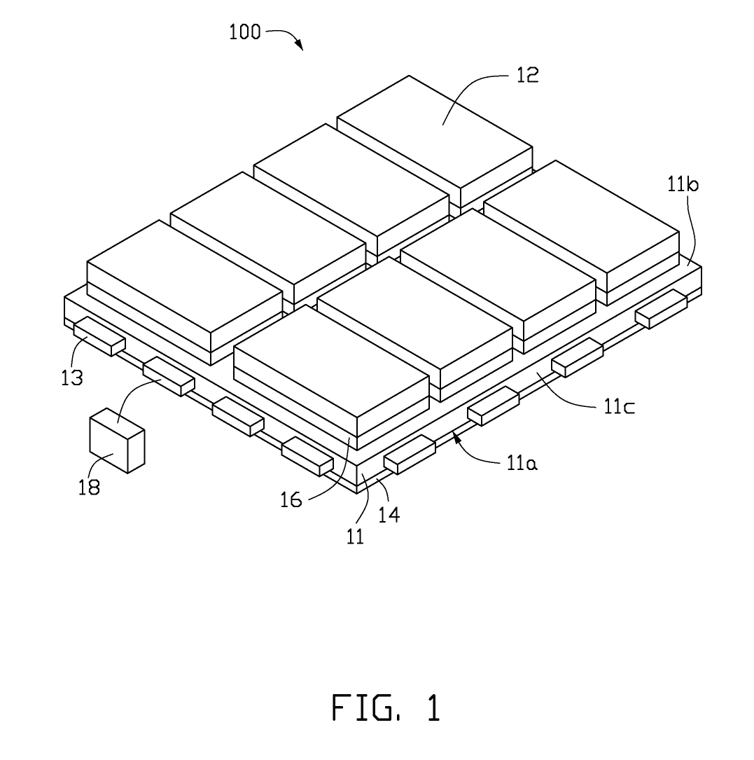

Referring to FIG. 1, a solar cell panel 100, in accordance with a first embodiment, includes a light-pervious substrate 11, a plurality of solar cell 12, a plurality of light sources 13, and a photo-catalyst film 14.

The substrate 11 includes a bottom surface 11a, a top surface 11b and four peripheral side surfaces 11c. The top surface 11b is opposite to the bottom surface 11a. The peripheral side surfaces 11c are interconnected between the bottom surface 11a and the top surface 11b. The substrate 11 is made of light-pervious materials, such as glass or plastic selected from a group consisting of polymethylmethacrylate (PMMA), poly carbonate, and silicone, etc. The photo-catalyst film 14 is formed on the bottom surface 11a, and exposed to air for decomposing contaminants deposited thereon. The photo-catalyst film 14 can be made of nanometer sized photo-catalyst material, such as tin oxide (SnO₂), zinc oxide (ZnO), tungsten oxide (WO₃), iron oxide (Fe₂O₃), SeTiO₃, cadmium selenide (CdSe), KTaO₃, cadmium sulfide (CdS) or niobium oxide (Nb₂O₅), etc. Preferably, the photo-catalyst film 14 is made of titanium dioxide (TiO₂) and formed on the bottom surface 11a by magnetron sputtering or electron beam deposition.

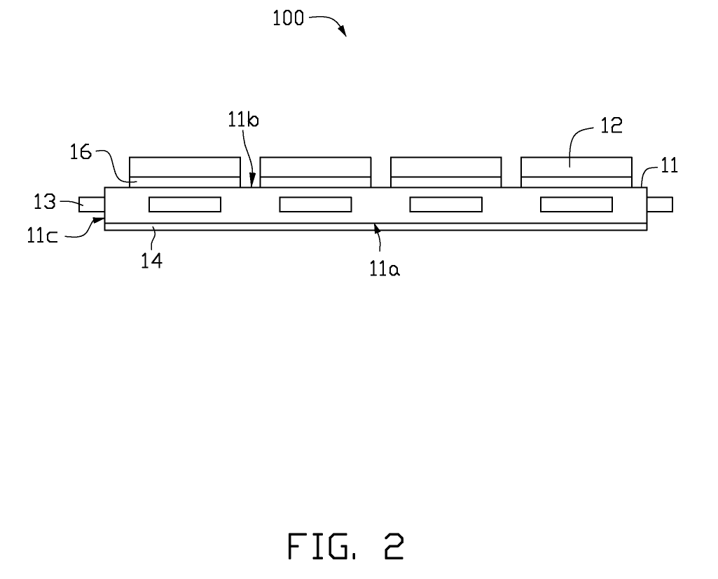

Referring to FIGS. 1 and 2, the solar cell panel 100 further includes a plurality of transparent conductive films 16 made of materials such as indium tin oxide (ITO), or indium zinc oxide (IZO). The transparent conductive films 16 are formed on the top surface 11b by semiconductor process. The solar cells 12 are used to convert light into usable electric energy, and are fixed to the substrate 11 with the transparent conductive films 16. The transparent conductive films 16 can be used to electrically connect the solar cell 12. The solar cell panel 100 may further include an electricity storage device (not shown), such as a storage battery electrically connected to the transparent conductive films 16. Thus, when the solar cell 12 converts light into electric energy, the electric energy can be stored in the electricity storage. The electric energy can be used to supply power to the light sources 13.

The solar cell 12 can be a silicon-based solar cell made of single crystal silicon, poly silicon or amorphous silicon. A material used for the solar cell 12 can also be selected from subgroup III-V semiconductor compounds, such as AlAs, InAs, InP, GaP, GaAs, GaN, and copper indium gallium selenide (CIGS), copper indium selenide (CIS), cadmium-tellurium (CdTe), organic material and dye-sensitized material, etc.

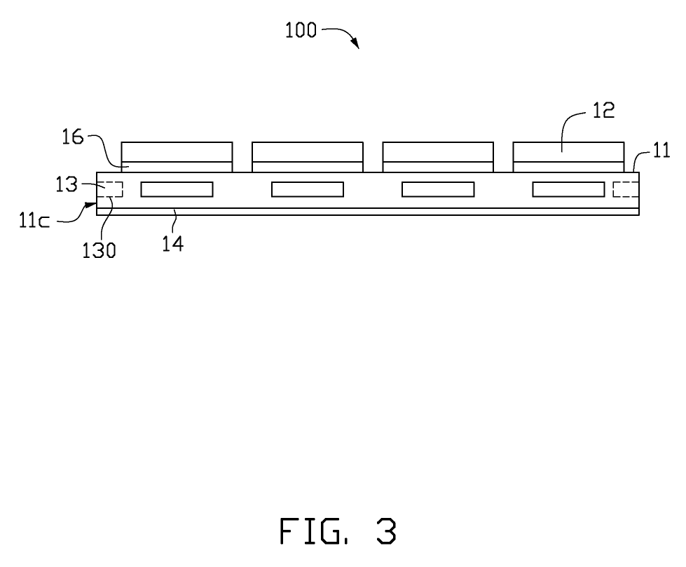

The light sources 13 can be ultraviolet (UV) lamps, such as UV fluorescent lamps and UV light emitting diodes. Preferably, the light sources 13 are UV light emitting diodes, and emit UV light with wavelength of less than 387 nm. In the present embodiment, the light sources 13 are arranged on the peripheral side surfaces 11c, and emit light into the substrate 11 through the peripheral side surfaces 11c. The light is transmitted by the substrate 11 and exit through the bottom surface 11a thereof, to be incident on the photo-catalyst film 14 thereon. Alternatively, a plurality of receiving recesses 130 can be defined on the peripheral side surfaces 11c for respectively receiving the light sources 13. Therefore, the solar cell panel 100 has smaller size, as shown in FIG. 3.

The solar cell panel 100 can be installed on a roof of a house, with the bottom surface 11a of the substrate 11 positioned to face outwardly, and the top surface 11b positioned to face the roof, such that solar light are received by the photo-catalyst film 14. The solar light is absorbed by the photo-catalyst film 14, with other parts of the solar light, such as visible light and infrared light further emitting into the substrate 11 through the bottom surfaces 11a. The solar light exits through the top surface 11b, and is then transmitted through the transparent conductive films 16 to the solar cells 12. The solar cells 12 absorb and convert the solar energy into electric energy. The electric energy is stored in the electricity storage, and then applied to lamps (not shown) to provide illumination.

In operation, the electric energy can also be applied to the UV light emitting diodes 13, thus the UV light emitting diodes 13 emit UV light on the photo-catalyst film 14. The photo-catalyst film 14 absorbs the UV light, and electron-hole pairs are excited from within the photo-catalyst film 14 to a surface thereof, to initiate reduction/oxidation reactions (redox) with organic contaminants adsorbed on the surface, achieving decomposition of the contaminants. Preferably, the UV light emitting diodes 13 can be electrically connected to a control switch 18, through which the electric energy is controlled by the control switch 18. Due to the photo-catalyst film 14 being exposed to the emission of the solar light to absorb the UV light, the UV light emitting diodes 13 can be switched off in daytime. In a dark environment/condition, the UV light emitting diodes 13 can be switched on to emit UV light on the photo-catalyst film 14. Therefore, by the provision of the UV light emitting diodes 13 and the photo-catalyst film 14, the solar cell panel 100 keeps clean, and energy converting efficiency of the solar cells 12 are ensure.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A solar cell panel, comprising
a light-pervious substrate having a bottom surface and an opposite top surface;
a photo-catalyst film formed on the bottom surface;
a light source for emitting light having a given wavelength to activate the photo-catalyst film to decompose contaminants thereon;
at least one solar cell positioned on the top surface of the substrate for absorbing and converting solar energy into electric energy.

2. The solar cell panel of claim 1, wherein the light source includes an ultraviolet light emitting diode.

3. The solar cell panel of claim 1, wherein the substrate further has a peripheral side surface interconnected between the bottom surface and the top surface, the light source is arranged on the peripheral side surface for emitting light into the substrate through the peripheral side surface.

4. The solar cell panel of claim 3, wherein a receiving recess is defined in the peripheral side surface of the substrate receiving the light source.

5. The solar cell panel of claim 1, wherein the at least one solar cell light source is electrically connected to the light source for supplying power to the light source.

6. The solar cell panel of claim 1, further comprising a control switch electrically connected to the light source for switching the light source on/off.

7. The solar cell panel of claim 1, wherein the photo-catalyst film is comprised of titanium dioxide.

8. The solar cell panel of claim 1, wherein the substrate is made of glass.

9. The solar cell panel of claim 1, further comprising a transparent conductive film sandwiched between the solar cell and the substrate.

10. The solar cell panel of claim 9, wherein a material of the transparent conductive film is selected from a group consisting of indium tin oxide and indium zinc oxide.
